(19) United States
(12) Patent Application Publication
(10) Pub. No.: US 2021/0279122 A1
(43) Pub. Date: Sep. 9, 2021

(54) LIFETIME TELEMETRY ON MEMORY ERROR STATISTICS TO IMPROVE MEMORY FAILURE ANALYSIS AND PREVENTION

(71) Applicant: Intel Corporation, Santa Clara, CA (US)

(72) Inventors: Shen ZHOU, Shanghai (CN); Cong LI, Shanghai (CN); Kuljit S. BAINS, Olympia, WA (US); Xiaoming DU, Shanghai (CN); Mariusz ORIOL, Gdynia (PL)

(21) Appl. No.: 17/317,745

(22) Filed: May 11, 2021

(51) Int. Cl. G06F 11/07

(52) U.S. Cl. CPC G06F 11/079; G06F 11/073; G11C 11/401; G06F 11/0787; G06F 11/076

(57) ABSTRACT

Methods and apparatus for lifetime telemetry on memory error statistics to improve memory failure analysis and prevention. Memory error information corresponding to detected correctable errors and uncorrectable memory errors are monitored, with the memory error information identifying an associated DRAM device in an associated DIMM. Corresponding micro-level error bits information from the memory error information is decoded and Micro-level Error Statistic Indicators (MESIs) are generated. Information associated with the MESIs from DRAM devices on the DIMMs are periodically written to persistent storage on those DIMMs. The MESIs for a given DIMM are updated over the lifetime of the DIMM.

### BACKGROUND INFORMATION

Memory failure is among the leading causes of server failures in datacenters. DIMM (Dual Inline Memory Module) vendors need to gain insight on the wear-out extent of the micro-level circuits/components of a memory module over its lifetime for both the field return-and-replacement decision and the future reliability design. The insight is also important to memory controller designers to enhance Intel RAS code (e.g., ECC algorithm), perform precise memory failure analysis, and accelerate troubleshooting. The information also serves as the building block for datacenter operators to build sophisticated uncorrectable error predictors in conjunction of using other impactful runtime context information (e.g., platform RAS settings, memory access information, etc.).

Existing platform RAS technologies typically count runtime errors and compare the error count within a time period with a pre-defined threshold. Memory test tools are intrusive, requiring a reboot to run and consequently impacting the availability of the servers.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified:

FIG. 1 is a diagram of a logical architecture used to implement a per-DIMM memory error telemetry data collection and tracking mechanism, according to one embodiment;

FIG. 2 is a flowchart illustrating high-level operations for generating and persistently storing MESIs (and/or associated information), according to one embodiment.

FIG. 3 is a diagram illustrating selective elements in a memory subsystem including a memory controller coupled to a DIMM showing two ranks of DRAM devices;

FIG. 4 is a schematic diagram of a DRAM memory structure illustrating four types of MESIs;

FIG. 5 is a diagram illustrating the format of data structures that stores MESI telemetry data in a secure storage accessible by the microcontroller/firmware/software, according to one embodiment;

FIG. 6 is a flowchart illustrating operations and logic for a high-level process flow on how MESI telemetry is gathered and maintained, according to one embodiment;

FIG. 7 is a flowchart illustrating operations performed during and intended clean system shutdown to write the most current MESIs to NVRAM.

FIG. 8 is a block diagram of an exemplary system in which aspects of the embodiments disclosed herein may be implemented.

### DETAILED DESCRIPTION

Embodiments of methods and apparatus for lifetime telemetry on memory error statistics to improve memory failure analysis and prevention are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

For clarity, individual components in the Figures herein may also be referred to by their labels in the Figures, rather than by a particular reference number. Additionally, reference numbers referring to a particular type of component (as opposed to a particular component) may be shown with a reference number followed by “(typ)” meaning “typical.” It will be understood that the configuration of these components will be typical of similar components that may exist but are not shown in the drawing Figures for simplicity and clarity or otherwise similar components that are not labeled with separate reference numbers. Conversely, “(typ)” is not to be construed as meaning the component, element, etc. is typically used for its disclosed function, implement, purpose, etc.

In accordance with aspects of the embodiments disclosed herein, a per-DIMM tracking mechanism is provided to count the micro-level error statistics of the memory throughout its lifecycle and store the indicators in a persistent storage with the DIMM. A microcontroller or firmware logic reads system and DIMM configurations, tracks the memory correctable errors (CEs) and detectable uncorrectable errors (DUEs) with micro-level error location information, and counts the error statistics down to bitlines, wordlines, banks, chips, and ranks. The set of indicators tracking the information are referred to herein as “micro-level error statistics indicators” (MESIs). The DIMM provides the persistent storage such as the Serial Presence Detect (SPD) table or other Non-Volatile Media (NVM). The microcontroller or firmware logic persistently stores MESIs to the persistent storage in the corresponding DIMM and exposures MESIs as the telemetry for DRAM health assessment and troubleshooting.

Having such MESIs for a large population of DIMMs allows DIMM vendors and memory RAS architects to refine the RAS design based on the field characteristics. For a single DIMM, the information allows the DIMM vendor to make a better return-and-replacement decision. It also allows users of the silicon and Intel to track the fault status of a DIMM over its lifetime in the field and to gather the critical information of aging effects of the memory.

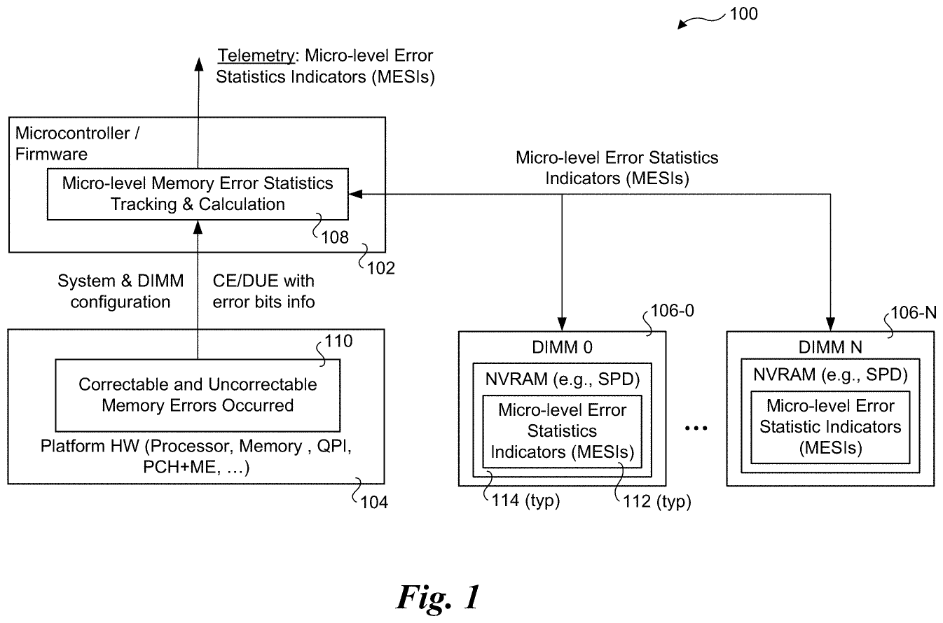

FIG. 1 shows a diagram of a logical architecture 100 used to implement the foregoing per-DIMM memory error telemetry data collection and tracking mechanism, according to one embodiment. Architecture 100 includes microcontroller/firmware 102, platform hardware (HW) 104, and multiple DIMMs 106-0 . . . 106-N. In one embodiment, microcontroller/firmware 102 represents functionality implemented by platform hardware including a logic block 108 for performing micro-level memory error statistics and tracking calculations. As described in further detail below, platform hardware 102 and or the functionality performed by logic block 108 may be implemented in a memory controller or may be implemented in platform hardware that is separate from the memory controller.

During runtime operations of hardware 104, correctable and uncorrectable memory errors 110 may occur. The correctable memory errors are also referred to herein as Correctable Errors (CEs) and the uncorrectable memory errors are also referred to herein as Detectable uncorrectable Errors (DUEs). As explained and illustrated in further detail below, the correctable and uncorrectable memory errors occur on DIMMs 106-0 . . . 106-N. In the illustrated embodiment in FIG. 1, MESIs 112 are stored in NVRAM (Non-Volatile Random Access Memory, a type of Non-Volatile Media) 114 on DIMMs 106-0 . . . 106-N.

During initialization of the platform hardware, system and DIMM configuration are detected, and associated information is provided to microcontroller/firmware 102 to be employed by logic block 108. During runtime operations of the platform, CEs and DUEs produced by memory in DIMMs 106-0 . . . 106-N are detected, and corresponding error bits information are generated by platform hardware, such as by a memory controller. The CEs and DUEs with error bits information is used by logic block 108 to generate the micro-level memory errors statistics. As described in detail below, MESIs 112 data are periodically written to NVRAM 114 on DIMMs 106-0 . . . 106-N.

The platform hardware, including integrated circuits provides the ability to monitor micro-level error information for CEs and DUEs of the memory, as well as detect system and DIMM configurations. As illustrated in FIG. 1, the DIMMs provide an accessible persistent storage infrastructure such as the Serial Presence Detect (SPD) table or other Non-Volatile Media.

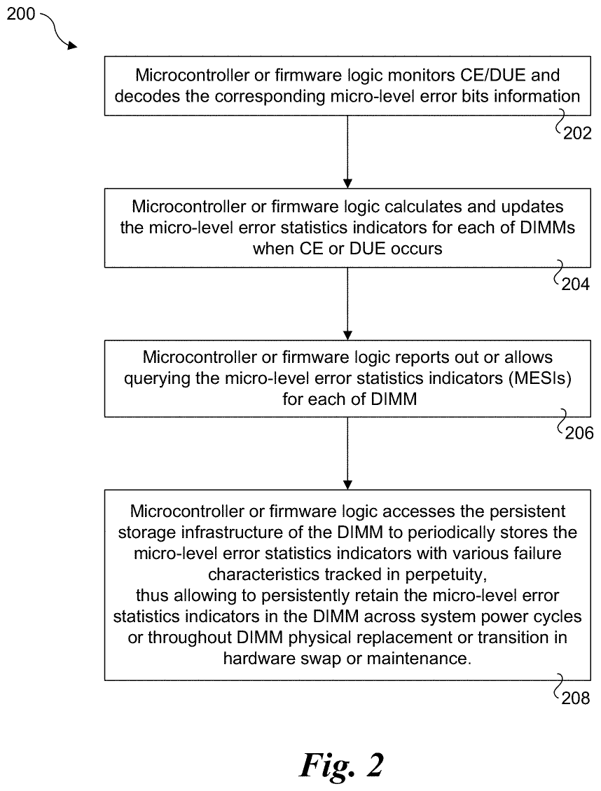

FIG. 2 shows a flowchart 200 illustrating high-level operations for generating and persistently storing MESIs (and/or associated information), according to one embodiment. In a block 202, the microcontroller or firmware logic monitors CEs and DUEs and decodes the corresponding micro-level error bits information by using capabilities provided by the platform hardware. In a block 204, the microcontroller or firmware logic calculates and updates the micro-level error statistics indicators for each of DIMMs 106-0 . . . 106-N when a CE or DUE occurs. In a block 206, the microcontroller or firmware logic reports out or allows querying the MESIs for each of DIMMs 106-0 . . . 106-N. In a block 208, the microcontroller or firmware logic accesses the persistent storage infrastructure of the DIMM (e.g., SPD or other Non-Volatile Media) to periodically stores the micro-level error statistics indicators with various failure characteristics tracked in perpetuity, thus allowing the DIMM to persistently retain the micro-level error statistics indicators across system power cycles or throughout DIMM physical replacement or transition in hardware swap or maintenance.

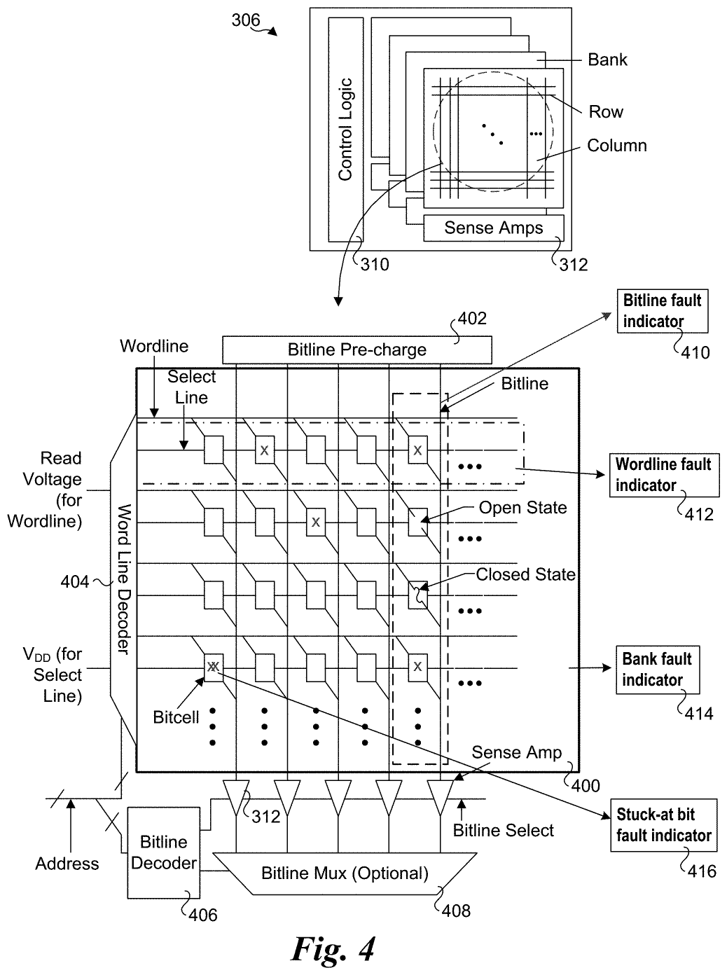

The telemetry of MESIs contains the most informative error statistics per DIMM to describe different types of faults in micro-level circuits/components. The error statistics are tracked over a period and are incrementally counted. Thus, processor vendors, DIMM vendors, OEMs or end users can consume the data for fast DIMM diagnostics of DIMM failures, DIMM health evaluation, and uncorrectable error prediction over the lifetime of a DIMM. Some non-limiting examples of the MESIs are shown in FIG. 4 and discussed below.

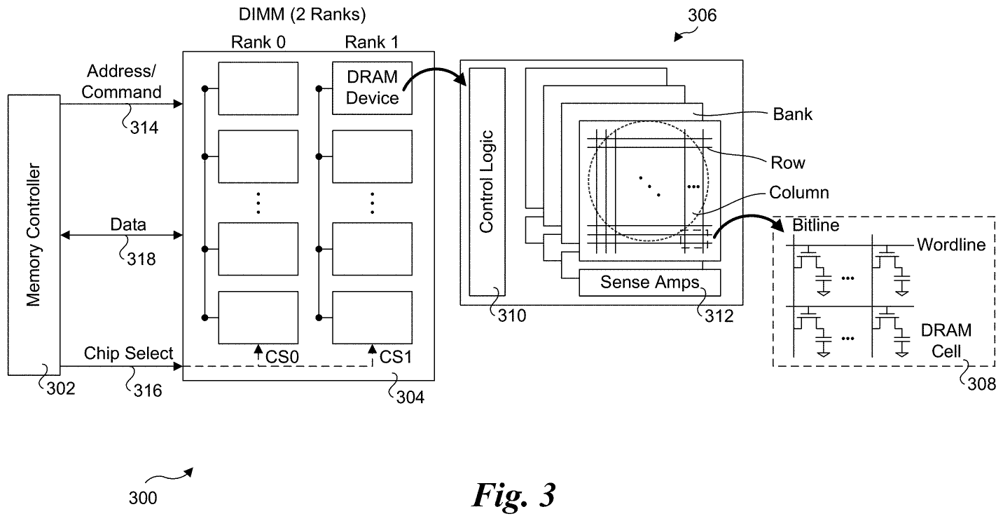

FIG. 3 shows selective elements in a memory subsystem 300 including a memory controller 302 coupled to a DIMM 304 showing two ranks of DRAM devices 306. Generally, a DRAM DIMM may have one or more ranks. Each DRAM device includes a plurality of banks comprising an array of DRAM cells 308 that are organized (laid out) and as rows and columns. Each row comprises a Wordline, while each column comprises a Bitline. Each DRAM device 306 further includes control logic 310 and sense amps 312 that are used to access DRAM cells 308.

As further shown in FIG. 3, memory controller provides inputs comprising address/commands 314 and chip select 316. For memory Writes, the memory controller inputs further include data 318 that are written to DRAM cells 308 based on the address and chip select inputs. Similarly, for Reads, data 318 stored in DRAM cells 308 identified by the address and chip select inputs is returned to memory controller 302.

As described herein, reference to memory devices (e.g., DRAM devices) can apply to different memory types. Memory devices may refer to volatile memory technologies. Volatile memory is memory whose state (and therefore the data stored on it) is indeterminate if power is interrupted to the device. Nonvolatile memory refers to memory whose state is determinate even if power is interrupted to the device. Dynamic volatile memory requires refreshing the data stored in the device to maintain state. One example of dynamic volatile memory includes DRAM, or some variant such as synchronous DRAM (SDRAM). A memory subsystem as described herein may be compatible with a number of memory technologies or standards, such as DDR3 (double data rate version 3, JESD79-3, originally published by JEDEC (Joint Electronic Device Engineering Council) on Jun. 27, 2007), DDR4 (DDR version 4, JESD79-4, originally published in September 2012 by JEDEC), LPDDR3 (low power DDR version 3, JESD209-3B, originally published in August 2013 by JEDEC), LPDDR4 (low power DDR version 4, JESD209-4, originally published by JEDEC in August 2014), WIO2 (Wide I/O 2 (WideIO2), JESD229-2, originally published by JEDEC in August 2014), HBM (high bandwidth memory DRAM, JESD235, originally published by JEDEC in October 2013), LPDDR5 (originally published by JEDEC in February 2019), HBM2 ((HBM version 2), originally published by JEDEC in December 2018), DDR5 (DDR version 5, originally published by JEDEC in July 2020), or others or combinations of memory technologies, and technologies based on derivatives or extensions of such specifications.

The (S)DRAM DIMMs that may be used comprise error correction code (ECC) memory. Error correction codes protects against undetected memory data corruption, and is used in computers and servers where such corruption is unacceptable, for example in some scientific and financial computing applications, cloud-based services, database and file servers, etc. ECC also reduces the number of crashes that are especially unacceptable in multi-user server applications and maximum-availability systems. The use of ECC DIMMs is well-known in the art. Existing hardware components, including memory controllers and the like and some DIMMs may be used to detect CEs and DUEs. Generally, the particular techniques and mechanisms used for detecting CEs and DUEs is outside the scope of this disclosure.

Under conventional (S)DRAM memory, data are generally accessed (Read and Written) using cachelines (also called cache lines) comprising a sequence of memory cells (bits) in a wordline. The cachelines for a given memory architecture generally have a predetermined width or size, such as 64 Bytes, noting other widths/sizes maybe used.

Referring to FIG. 4, the DRAM device 306 structure includes a bank 400 including an array of memory cells called bitcells organized as wordlines and bitlines. A bitcell may have an open state or closed state. A bitline pre-charge 402 and a word inline decoder 404 are coupled to bank 400. A bitline decoder 406 is used for selecting bitlines. An optional bitline mux (multiplexer) 408 may be used to multiplex the outputs of sense amps 312.

FIG. 4 shows four examples of MESIs. These include a bitline fault indicator 410, a wordline fault indicator 412, a bank fault indicator 414, and a stuck-at bit fault indicator 416.

A bitline fault indicator 416 comprises the number of accumulated unique fault locations and the minimum faulty range for a specific bitline. For a bitline, we track 1) the number of unique locations with errors observed and 2) the minimum range that covers those locations (e.g., maximum wordline index and minimum wordline index with errors observed). To keep the telemetry concise, one may only keep a set of bitlines with the largest location numbers or those with the largest ranges in the persistent storage, in one embodiment.

The following is a bitline fault indicator example:
<bitline ID=128, # of unique fault locations=200, minimum faulty range <minimum wordline index=12, maximum wordline index=3000>>

A wordline fault indicator comprises the number of accumulated unique fault locations and the minimum faulty range for a specific wordline. Like the bitline indicator, for a wordline, we track 1) the number of unique locations with errors observed and 2) the minimum range that covers those locations (e.g., maximum bitline index and minimum bitline index with errors observed). To keep the telemetry concise, one may only keep a set of wordlines with the largest location numbers or those with the largest range in the persistent storage, in one embodiment.

The following is a wordline fault indicator example:
<wordline ID=512, # of unique fault locations=100, minimum faulty range <minimum bitline index=500, maximum bitline index=700>>

A bank fault indicator comprises the number of accumulated unique fault locations and the minimum faulty rectangle area. For a bank, we track 1) the number of unique location with errors observed and 2) the minimum rectangle covering those locations (maximum/minimum bitline/wordline index with errors observed).

The following is an example of a bank fault indicator:
<Bank ID=10, # of unique fault locations=50, minimum faulty rectangle area<minimum bitline index=2, maximum bitline index=50, minimum wordline index=100, maximum wordline index=2000>>

A struck-at bit fault indicator comprises the number of accumulated errors observed in a specific bit over pre-defined stuck-at bit error threshold. To keep the telemetry concise, one may only keep a set of bits with the largest numbers in the persistent storage. The following is an example of a struck-at bit fault indicator:
<Bit location<bitline index=10, workline index=100>, # of accumulated errors=2000>

The MESIs are not limited to the examples listed above but could contain other critical memory faulty characteristics over the lifetime of the memory, such as accumulated uptimes of the DIMM, accumulated # of boots, and so on.

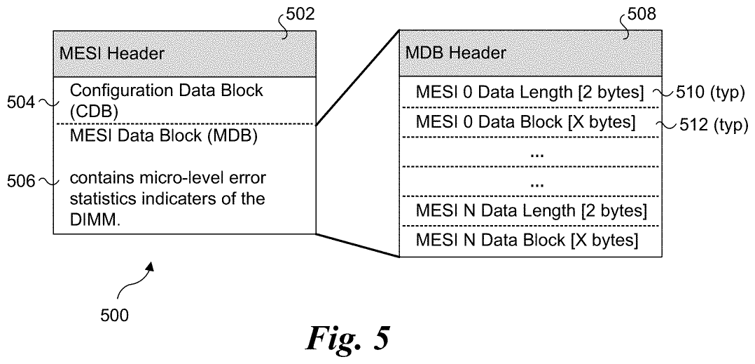

FIG. 5 shows diagram 500 illustrating the format of data structures that stores MESI telemetry data in a secure storage accessible by the microcontroller/firmware/software, according to one embodiment. The data structures include a MESI header 502, configuration data block (CDB) 504, and a MESI data block (MDB) 506. CDB 504 may contain the runtime context of the memory such as uptimes and number of boots. MDB 506 contains MESIs of the DIMM, and includes an MDB header 508 and a plurality of MESI entries comprising a MESI data length 510 followed by a MESI data block (data) 512.

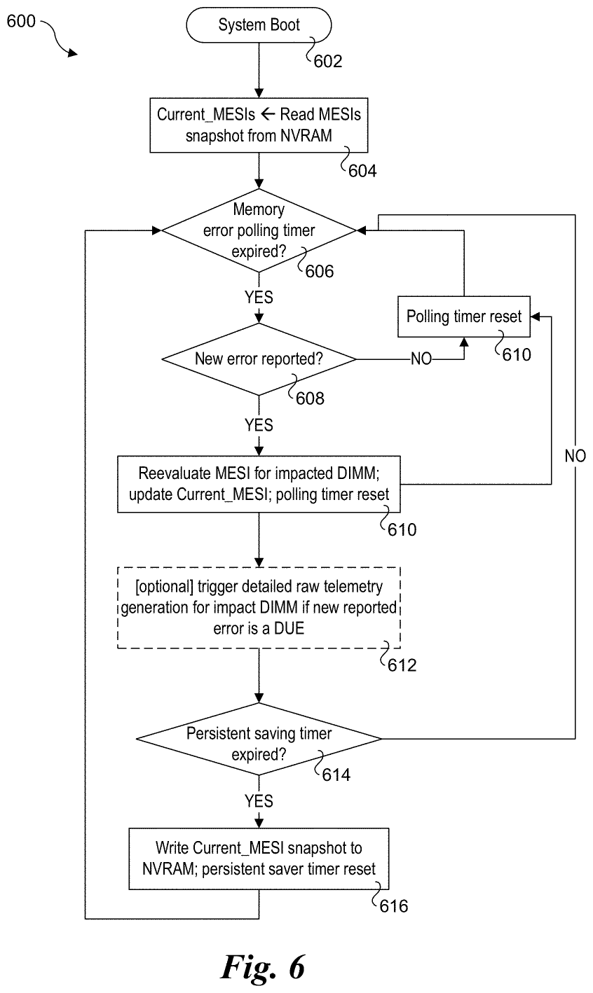

FIG. 6 shows a flowchart 600 illustrating operations and logic for a high-level process flow on how MESI telemetry is gathered and maintained, according to one embodiment. The process begins with a system boot 602. In a block 604 the current MESIs are read from an MESIs snapshot from NVRAM on the DIMM for one or more DIMMs. The remaining operations and logic are implemented on an ongoing, loop-wise manner.

In this example, a polling timer is used. As shown by a decision block 606, a determination is made to whether the memory error polling timer expired. When the polling timer has expired, the logic proceeds to a decision block 608 in which a determination is made to whether a new error has been reported. If the answer is NO, the logic proceeds to a block 609 in which the polling timer is reset, and the logic flows back to decision block 606.

In the event one or more new errors are reported, the logic proceeds to a block 610 in which the MESI is reevaluated for the impacted DIMM. The current MESI snapshot is also updated, and the polling timer is reset. In an optional block 612, detailed raw telemetry generation is triggered for the impact on the DIM if the new reported error is a DUE.

In a decision block 614 a determination is made to whether a persistent saving time has expired. The persistent saving timer is used to periodically write the current MESI snapshot to NVRAM on the DIMM. Thus, upon expiration of the persistent saving timer, the result of decision block 614 will be YES and the current MESIs snapshot will be written to NVRAM in a block 616. The process will then loop back to decision block 606, and the process will be repeated in an ongoing manner.

In addition to using a polling timer, other mechanisms may be used. For example, platform hardware used to detect memory errors may employ an interrupt mechanism that may be used to inform the telemetry collection mechanism when new CEs and/or DUES are detected.

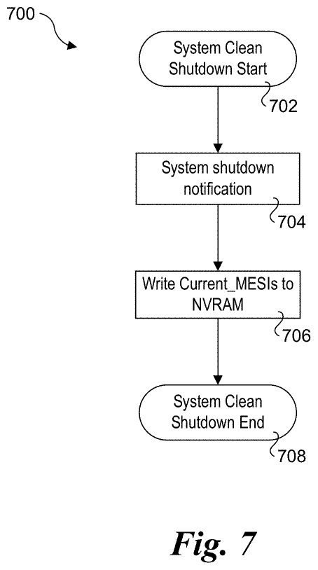

FIG. 7 shows a flowchart 700 illustrating operations performed during and intended clean system shutdown to write the most current MESIs to NVRAM. The process begins in a start block 702 in which the clean system shutdown begins. In a block 704, a system shutdown notification is sent to the microcontroller/firmware used to monitor and store the MESIs for the system. In a block 706 the current MESIs for each DIMM for which MESIs are tracked are written to NVRAM on those DIMMs. As shown in an end block 708, the process is completed with the end of the clean system shutdown.

### Example Compute Platform

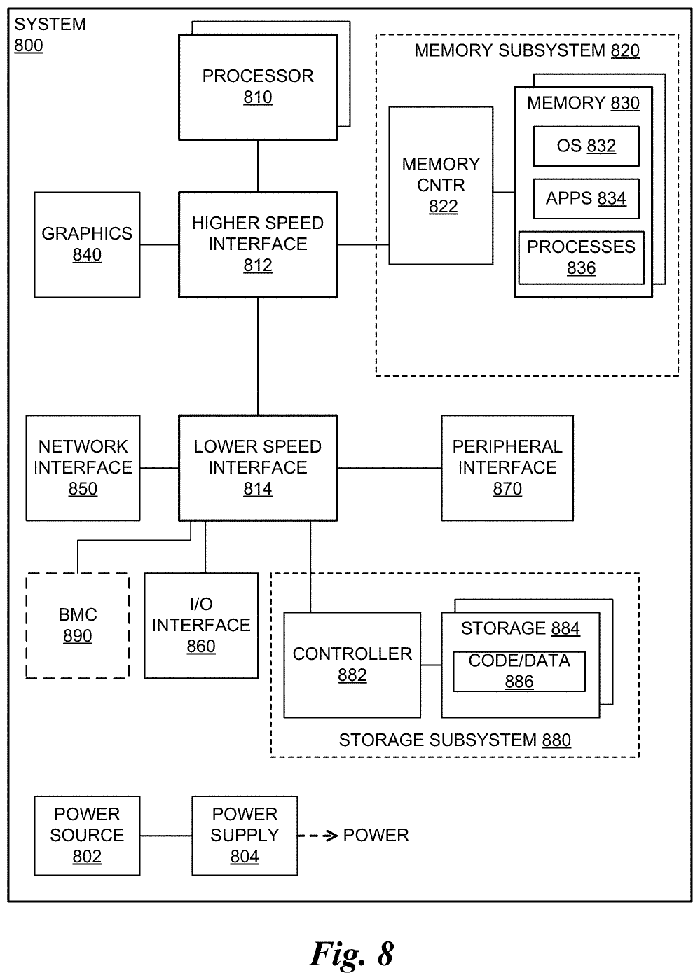

FIG. 8 illustrates an example compute platform 800 in which aspects of the embodiments may be practiced. Compute platform 800 represents a computing device or computing system in accordance with any example described herein, and can be a server, laptop computer, desktop computer, or the like. More generally, compute platform 800 is representative of any type of computing device or system employing DRAM DIMMs.

Compute platform 800 includes a processor 810, which provides processing, operation management, and execution of instructions for compute platform 800. Processor 810 can include any type of microprocessor, central processing unit (CPU), graphics processing unit (GPU), processing core, or other processing hardware to provide processing for compute platform 800, or a combination of processors. Processor 810 controls the overall operation of compute platform 800, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one example, compute platform 800 includes interface 812 coupled to processor 810, which can represent a higher speed interface or a high throughput interface for system components that needs higher bandwidth connections, such as memory subsystem 820 or graphics interface components 840. Interface 812 represents an interface circuit, which can be a standalone component or integrated onto a processor die. Where present, graphics interface 840 interfaces to graphics components for providing a visual display to a user of compute platform 800. In one example, graphics interface 840 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one example, the display can include a touchscreen display. In one example, graphics interface 840 generates a display based on data stored in memory 830 or based on operations executed by processor 810 or both. In one example, graphics interface 840 generates a display based on data stored in memory 830 or based on operations executed by processor 810 or both.

Memory subsystem 820 represents the main memory of compute platform 800 and provides storage for code to be executed by processor 810, or data values to be used in executing a routine. Memory 830 of memory subsystem 820 may include one or more memory devices such as DRAM DIMMs, read-only memory (ROM), flash memory, or other memory devices, or a combination of such devices. Memory 830 stores and hosts, among other things, operating system (OS) 832 to provide a software platform for execution of instructions in compute platform 800. Additionally, applications 834 can execute on the software platform of OS 832 from memory 830. Applications 834 represent programs that have their own operational logic to perform execution of one or more functions. Processes 836 represent agents or routines that provide auxiliary functions to OS 832 or one or more applications 834 or a combination. OS 832, applications 834, and processes 836 provide software logic to provide functions for compute platform 800. In one example, memory subsystem 820 includes memory controller 822, which is a memory controller to generate and issue commands to memory 830. It will be understood that memory controller 822 could be a physical part of processor 810 or a physical part of interface 812. For example, memory controller 822 can be an integrated memory controller, integrated onto a circuit with processor 810.

While not specifically illustrated, it will be understood that compute platform 800 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or an Institute of Electrical and Electronics Engineers (IEEE) standard 1394 bus.

In one example, compute platform 800 includes interface 814, which can be coupled to interface 812. Interface 814 can be a lower speed interface than interface 812. In one example, interface 814 represents an interface circuit, which can include standalone components and integrated circuitry. In one example, multiple user interface components or peripheral components, or both, couple to interface 814. Network interface 850 provides compute platform 800 the ability to communicate with remote devices (e.g., servers or other computing devices) over one or more networks. Network interface 850 can include an Ethernet adapter, wireless interconnection components, cellular network interconnection components, USB (universal serial bus), or other wired or wireless standards-based or proprietary interfaces. Network interface 850 can exchange data with a remote device, which can include sending data stored in memory or receiving data to be stored in memory.

In one example, compute platform 800 includes one or more I/O interface(s) 860. I/O interface(s) 860 can include one or more interface components through which a user interacts with compute platform 800 (e.g., audio, alphanumeric, tactile/touch, or other interfacing). Peripheral interface 870 can include any hardware interface not specifically mentioned above. Peripherals refer generally to devices that connect dependently to compute platform 800. A dependent connection is one where compute platform 800 provides the software platform or hardware platform or both on which operation executes, and with which a user interacts.

In one example, compute platform 800 includes storage subsystem 880 to store data in a nonvolatile manner. In one example, in certain system implementations, at least certain components of storage subsystem 880 can overlap with components of memory subsystem 820. Storage subsystem 880 includes storage device(s) 884, which can be or include any conventional medium for storing large amounts of data in a nonvolatile manner, such as one or more magnetic, solid state, or optical based disks, or a combination. Storage device(s) 884 holds code or instructions and data 886 in a persistent state (i.e., the value is retained despite interruption of power to compute platform 800). A portion of the code or instructions may comprise platform firmware that is executed on processor 810. Storage device(s) 884 can be generically considered to be a “memory,” although memory 830 is typically the executing or operating memory to provide instructions to processor 810. Whereas storage device(s) 884 is nonvolatile, memory 830 can include volatile memory (i.e., the value or state of the data is indeterminate if power is interrupted to compute platform 800). In one example, storage subsystem 880 includes controller 882 to interface with storage device(s) 884. In one example controller 882 is a physical part of interface 814 or processor 810 or can include circuits or logic in both processor 810 and interface 814.

Compute platform 800 may include an optional Baseboard Management Controller (BMC) 890 that is configured to effect the operations and logic corresponding to the flowcharts disclosed herein. BMC 890 may include a microcontroller or other type of processing element such as a processor core, engine or micro-engine, that is used to execute instructions to effect functionality performed by the BMC. Optionally, another management component (standalone or comprising embedded logic that is part of another component) may be used.

Power source 802 provides power to the components of compute platform 800. More specifically, power source 802 typically interfaces to one or multiple power supplies 804 in compute platform 800 to provide power to the components of compute platform 800. In one example, power supply 804 includes an AC to DC (alternating current to direct current) adapter to plug into a wall outlet. Such AC power can be renewable energy (e.g., solar power) power source 802. In one example, power source 802 includes a DC power source, such as an external AC to DC converter. In one example, power source 802 can include an internal battery or fuel cell source.

In some embodiments, the functionality ascribed to the firmware discussed in the embodiments herein comprise firmware instructions that are executed on processor 810 or an embedded processor, processing element, microcontroller, micro-engine, etc. In one embodiment, compute platform may include other types of management components that may collect the memory error telemetry data and/or generate the MESIs, such as a manageability engine embedded on processor 810 (not shown).

Although some embodiments have been described in reference to particular implementations, other implementations are possible according to some embodiments. Additionally, the arrangement and/or order of elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. Additionally, “communicatively coupled” means that two or more elements that may or may not be in direct contact with each other, are enabled to communicate with each other. For example, if component A is connected to component B, which in turn is connected to component C, component A may be communicatively coupled to component C using component B as an intermediary component.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Generally, the functionality provided by embodiments disclosed herein may be implemented via one or more forms of embedded logic. As used herein, including the claims, embedded logic comprises various forms of circuitry with or configured to implement logic including but not limited to processors, CPUs, microengines, microcontrollers, FPGAs and other programmable logic devices, ASICs (Application Specific integrated Circuits), Graphic Processing Units (GPUs), and various forms of accelerators, etc. The logic may be implemented by programming the physical hardware (e.g., for FPGAs and other programmable logic devices and ASICs) and/or via execution of instructions on one or more processing elements, such as a processor core, microengine, microcontroller, and processing elements in GPUs and accelerators. Hybrid devices may be implemented with more than one form of embedded logic.

As discussed above, various aspects of the embodiments herein may be facilitated by corresponding embedded software and/or firmware components, such as embedded software and/or firmware executed by an embedded processor or the like and firmware executed on a system's processor of CPU. Thus, embodiments of this invention may be used as or to support a software program, software/firmware modules, and firmware instructions executed upon some form of processor, processing core or embedded logic a virtual machine running on a processor or core or otherwise implemented or realized upon or within a non-transitory computer-readable or machine-readable storage medium. A non-transitory computer-readable or machine-readable storage medium includes any mechanism for storing or transmitting information in a form readable by a machine (e.g., a computer). For example, a non-transitory computer-readable or machine-readable storage medium includes any mechanism that provides (i.e., stores and/or transmits) information in a form accessible by a computer or computing machine (e.g., computing device, electronic system, etc.), such as recordable/non-recordable media (e.g., read only memory (ROM), random access memory (RAM), magnetic disk storage media, optical storage media, flash memory devices, etc.). The content may be directly executable (“object” or “executable” form), source code, or difference code (“delta” or “patch” code). A non-transitory computer-readable or machine-readable storage medium may also include a storage or database from which content can be downloaded. The non-transitory computer-readable or machine-readable storage medium may also include a device or product having content stored thereon at a time of sale or delivery. Thus, delivering a device with stored content, or offering content for download over a communication medium may be understood as providing an article of manufacture comprising a non-transitory computer-readable or machine-readable storage medium with such content described herein.

The operations and functions performed by various components described herein may be implemented by software running on a processing element, via embedded hardware or the like, or any combination of hardware and software. Such components may be implemented as software modules, hardware modules, special-purpose hardware (e.g., application specific hardware, ASICs, DSPs, etc.), embedded controllers, hardwired circuitry, hardware logic, etc. Software content (e.g., data, instructions, configuration information, etc.) may be provided via an article of manufacture including non-transitory computer-readable or machine-readable storage medium, which provides content that represents instructions that can be executed. The content may result in a computer performing various functions/operations described herein.

As used herein, a list of items joined by the term “at least one of” can mean any combination of the listed terms. For example, the phrase “at least one of A, B or C” can mean A; B; C; A and B; A and C; B and C; or A, B and C.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the drawings. Rather, the scope of the invention is to be determined entirely by the following claims, which are to be construed in accordance with established doctrines of claim interpretation.

What is claimed is:

1. An apparatus configured to be implemented in a computing platform comprising platform hardware including a plurality of Dynamic Random Access Memory (DRAM) devices on one of more Dual Inline Memory Modules (DIMMs) and a processor having an integrated or separate memory controller used to access memory in the plurality of DRAM devices, comprising:
embedded logic to,
monitor memory error information corresponding to at least one of detected correctable errors and uncorrectable memory errors, the memory error information for a given correctable or uncorrectable memory error identifying an associated DRAM device;
decode corresponding micro-level error bits information from the memory error information and generate Micro-level Error Statistic Indicators (MESIs); and
cause information associated with the MESIs generated for DRAM devices on a given DIMM to be written to persistent storage on that DIMM.

2. The apparatus of claim 1, wherein the DRAM devices comprise banks with arrays of memory cells organized in wordlines and bitlines, and wherein the MESIs include bitline fault indicators associated with specific bitlines.

3. The apparatus of claim 1, wherein the DRAM devices comprise banks with arrays of memory cells organized in wordlines and bitlines, and wherein the MESIs include wordline fault indicators associated with specific wordlines.

4. The apparatus of claim 1, wherein the DRAM devices comprise banks with arrays of memory cells organized in wordlines and bitlines, and wherein the MESIs include bank fault indicators associated with specific banks or areas on specific banks.

5. The apparatus of claim 1, wherein the DRAM devices comprise banks with arrays of memory cells organized in wordlines and bitlines comprising bits, and wherein the MESIs include stuck-at bit indicators associated with specific bits.

6. The apparatus of claim 1, wherein the apparatus comprises one of a baseband management controller or other platform management entity.

7. The apparatus of claim 1, wherein the apparatus comprises a microcontroller.

8. The apparatus of claim 1, wherein the apparatus comprises the processor, and the embedded logic includes a portion of platform firmware that is executed on the processor.

9. The apparatus of claim 1, wherein the MESIs information is stored in a data structure including a MESI data block comprising a plurality of MESI data block entries.

10. The apparatus of claim 1, wherein the embedded logic is further to:
calculate and update MESIs for each of the one or more DIMMs when correctable errors or detectable uncorrectable memory errors occur; and
periodically cause information associated with the MESIs including the updated MESIs to be written to persistent storage in the one or more DIMMs.

11. A compute platform, comprising:
a processor;
a plurality of Dual Inline Memory Modules (DIMMs), each comprising a plurality of Dynamic Random Access Memory (DRAM) devices comprising memory and including a plurality of banks of memory cells organized in arrays comprising row-wise wordlines and column-wise bitlines;
a memory controller coupled to the plurality of DIMMs and used to access the memory, the memory controller integrated on the processor or coupled to the processor and enabled to detect correctable errors and uncorrectable errors; and
embedded logic to:
monitor memory error information corresponding to at least one of detected correctable errors and uncorrectable memory errors, the memory error information for a given correctable or uncorrectable memory error identifying an associated DRAM device;
decode corresponding micro-level error bits information from the memory error information and generate Micro-level Error Statistic Indicators (MESIs); and
cause information associated with the MESIs generated for DRAM devices on a given DIMM to be written to persistent storage on that DIMM.

12. The compute platform of claim 11, wherein the embedded logic is implemented in one of a baseband management controller or other platform management entity.

13. The compute platform of claim 11, wherein the DRAM devices comprise banks with arrays of memory cells organized in wordlines and bitlines, and wherein the MESIs include at least one of bitline fault indicators associated with specific bitlines and wordline fault indicators associated with specific wordlines.

14. The compute platform of claim 11, wherein the DRAM devices comprise banks with arrays of memory cells organized in wordlines and bitlines, and wherein the MESIs include bank fault indicators associated with specific banks or areas on specific banks.

15. The compute platform of claim 11, wherein the embedded logic is further to:
calculate and update MESIs for each of the one or more DIMMs when correctable errors or detectable uncorrectable memory errors occur; and
periodically cause information associated with the MESIs including the updated MESIs to be written to persistent storage in the one or more DIMMs.

16. A method implemented in a computing platform comprising platform hardware including a plurality of Dynamic Random Access Memory (DRAM) devices on one of more Dual Inline Memory Modules (DIMMs) comprising:
monitoring memory error information corresponding to at least one of detected correctable errors and uncorrectable memory errors, the memory error information for a given correctable or uncorrectable memory error identifying an associated DRAM device in an associated DIMM;
decoding corresponding micro-level error bits information from the memory error information and generating Micro-level Error Statistic Indicators (MESIs); and
causing information associated with the MESIs generated for DRAM devices on a given DIMM to be written to persistent storage on that DIMM.

17. The method of claim 16, wherein the DRAM devices comprise banks with arrays of memory cells organized in wordlines and bitlines, and wherein the MESIs include at least one of bitline fault indicators associated with specific bitlines and wordline fault indicators associated with specific wordlines.

18. The method of claim 16, wherein the DRAM devices comprise banks with arrays of memory cells organized in wordlines and bitlines, and wherein the MESIs include bank fault indicators associated with specific banks or areas on specific banks.

19. The method of claim 16, wherein the DRAM devices comprise banks with arrays of memory cells organized in wordlines and bitlines comprising bits, and wherein the MESIs include at least one of stuck-at bit indicators associated with specific bits and bank fault indicators associated with specific banks or areas on specific banks.

20. The method of claim 16, further comprising
calculating and updating MESIs for each of the one or more DIMMs when correctable errors or detectable uncorrectable memory errors occur; and
periodically causing information associated with the MESIs including the updated MESIs to be written to persistent storage in the one or more DIMMs.
